(19) United States
(12) Patent Application Publication
(10) Pub. No.: US 2021/0235178 A1
(43) Pub. Date: Jul. 29, 2021

(54) SLIDING RAIL STRUCTURE OF MOBILE POWER SUPPLY

(71) Applicant: XIAMEN PADMATE TECHNOLOGY CO., LTD., Xiamen (CN)

(72) Inventor: Xiaolu CAI, Xiamen (CN)

(21) Appl. No.: 17/229,496

(22) Filed: Apr. 13, 2021

Related U.S. Application Data
(63) Continuation of application No. PCT/CN2019/076313, filed on Oct. 26, 2019.

(30) Foreign Application Priority Data
Oct. 26, 2018 (CN) 201821752388.0

(51) Int. Cl. H04R 1/02; H04R 1/10; H05K 5/03; H05K 7/18

(52) U.S. Cl. CPC H04R 1/028; H04R 1/1025; H04R 2420/07; H05K 7/183; H05K 5/03

(57) ABSTRACT

Disclosed is a sliding rail structure of a mobile power supply, comprising a cover body and a main body of the mobile power supply, a surface of the main body of the mobile power supply fitting with the cover body is recessed to form at least one Bluetooth headset holder, and a sliding connection assembly is connected between the cover body and the main body of the mobile power supply; the sliding connection assembly includes a first connection member, a second connection member and a reset member; after adopting the above structure, the user only needs to operate the Bluetooth headset with single hand when picking and placing it, when the cover body no longer blocks the Bluetooth headset holder, the Bluetooth headset can be placed in the Bluetooth headset holder and charged, or the Bluetooth headset can be picked up, which is convenient and quick to operate.

### CROSS REFERENCE TO RELATED APPLICATIONS

This application is a Continuation of co-pending Application No. PCT/CN2019/076313, filed on 26 Oct. 2019, for which priority is claimed under 35 U.S.C. § 120; and this application claims priority of Application No. CN 201821752388.0 filed in China on 26 Oct. 2019 under 35 U.S.C. § 119; the entire contents of all of which are hereby incorporated by reference.

### TECHNICAL FIELD

The present invention relates to the field of mobile power supply, and particularly refers to a sliding rail structure of a mobile power supply.

### BACKGROUND

Bluetooth headsets apply the Bluetooth technology to hands-free headsets, and enable users to avoid the interference of annoying wires, thereby making easy calls freely in various ways. Since the advent of the Bluetooth headsets, they are always good tools for mobile business people to improve efficiency. Existing mobile power supplies specially used for charging Bluetooth headsets are compact in appearance, convenient to carry, and can be used as storage boxes for the Bluetooth headsets, thus, they are deeply loved by business people.

The Bluetooth headsets are generally used in scenarios where the users have other events that need to be handled, and they are not convenient to hold the mobile phone to answer. A storage structure design of the mobile power supply of the existing Bluetooth headset mostly adopts manners such as a flip cover, a rotary cover, a pop cover, etc., and even a cover body and a main body of the mobile power supply are buckled together. The above structure design needs two hands to assist each other in the practical operation to complete opening and closing the cover body and picking and placing the Bluetooth headset, it will cause unnecessary trouble and waste of time when picking and placing the Bluetooth headset, and bring poor user experience.

In view of this, the present inventor conducts a deep conception and makes an active research, improvement and trial so as to develop and design the present invention with respect to many deficiencies and inconveniences caused by imperfection in the above structure design.

### SUMMARY

The object of the present invention is to provide a sliding rail structure of a mobile power supply, which is convenient for picking and placing the Bluetooth headset with single hand and is convenient for operation, thereby improving the user experience.

In order to achieve the above object, the solution of the present invention is: a sliding rail structure of a mobile power supply, includes a cover body and a main body of the mobile power supply, a surface of the main body of the mobile power supply fitting with the cover body is recessed inwardly to form at least one Bluetooth headset holder for placing and charging the Bluetooth headset, and a sliding connection assembly is connected between the cover body and the main body of the mobile power supply; the sliding connection assembly includes a first connection member, a second connection member and a reset member, the first connection member is fixed on a surface of the cover body facing the main body of the mobile power supply, the second connection member is fixed on a surface of the main body of the mobile power supply facing the cover body, the first connection member is slidably connected to the second connection member, and the reset member is connected between the first connection member and the second connection member.

The surface of the main body of the mobile power supply fitting with the cover body is formed with a mounting groove for mounting the sliding connection assembly, which is located beside the Bluetooth headset holder; the second connection member is fixedly mounted in the mounting groove.

The second connection member is formed with a sliding groove, an orientation of the sliding groove is consistent with that of the mounting groove, and the first connection member is formed with a sliding rail movably fitting with the sliding groove.

The surface of the cover body fitting with the main body of the mobile power supply is formed with a mounting cavity for mounting the sliding connection assembly, the first connection member is fixedly mounted in the mounting cavity.

The first connection member is formed with a sliding groove, the second connection member is formed with the sliding rail movably fitting with the sliding groove, and the mounting cavity is formed with a notch through which the sliding rail is disposed to pass at a position corresponding to two ends of the sliding groove.

The reset member is a steel wire having at least one bend, and two ends of the steel wire are respectively connected to the first connection member and the second connection member.

The main body of the mobile power supply is provided with a USB port for supplying power to other electronic apparatuses.

After adopting the above structure, the user only needs to operate the Bluetooth headset with single hand when picking and placing it, a palm grips the main body of the mobile power supply, a thumb presses and moves the cover body to a side of the main body of the mobile power supply, at this time, the first connection member is slidably connected to the second connection member, when the cover body is opened to be in the state where it no longer blocks the Bluetooth headset holder, the Bluetooth headset can be placed in the Bluetooth headset holder and charged, or the Bluetooth headset can be picked up, which is convenient and quick to operate and avoids waste of time, thereby improving the user experience.

In addition, when the operation of placing and picking the Bluetooth headset is completed, the above reset member can make the first connection member quickly reset to an initial state, that is, the cover body is reset to be in the state of covering the Bluetooth headset holder, to prevent the user from forgetting to close the cover body and causing the Bluetooth headset to be dropped and lost; and the above main body of the mobile power supply is further provided with the USB port, which can supply power to other electronic apparatuses, thereby enriching the use of the present invention.

### BRIEF DESCRIPTION OF DRAWINGS

FIG. 1 is an exploded view of a closed state of a first embodiment of the present invention;

FIG. 2 is a sectional view of the closed state of the first embodiment of the present invention;

FIG. 3 is an exploded view of an opened state of the first embodiment of the present invention;

FIG. 4 is a sectional view of the opened state of the first embodiment of the present invention;

FIG. 5 is an exploded view of a closed state of a second embodiment of the present invention;

FIG. 6 is a sectional view of the closed state of the second embodiment of the present invention;

FIG. 7 is an exploded view of an opened state of the second embodiment of the present invention; and

FIG. 8 is a sectional view of the opened state of the second embodiment of the present invention.

### EXPLANATION FOR REFERENCE NUMBERS

1. Cover Body; 2. Main Body of Mobile Power Supply; 20. USB Port; 21. Bluetooth Headset Holder; 22. Mounting Groove; 3. Sliding Connection Assembly; 31. First Connection Member; 32. Second Connection Member; 33. Reset Member.

### DETAILED DESCRIPTION OF EMBODIMENTS

In order to further explain the technical solution of the present invention, the present invention will be described in detail through specific embodiments below.

For the convenience of description, the following ‘up’, ‘down’, ‘left’ and ‘right’ are consistent with the up, down, left and right directions of the drawings themselves, but they do not limit the structure of the present invention.

A sliding rail structure of a mobile power supply may include a cover body 1 and a main body 2 of the mobile power supply, a sliding connection assembly 3 may be connected between the cover body 1 and the main body 2 of the mobile power supply. The above sliding connection assembly 3 may include a first connection member 31, a second connection member 32 and a reset member 33, the first connection member 31 is fixed on a surface of the cover body 1 facing the main body 2 of the mobile power supply, the second connection member 32 is fixed on a surface of the main body 2 of the mobile power supply facing the cover body 1, the first connection member 31 is slidably connected to the second connection member 32, and the reset member 33 is connected between the first connection member 31 and the second connection member 32.

The surface of the above main body 2 of the mobile power supply fitting with the cover body 1 may be recessed inwardly to form at least one Bluetooth headset holder 21 for placing and charging the Bluetooth headset, thus, the above cover body 1 movably covers the Bluetooth headset holder 21, so that the Bluetooth headset holder 21 forms a movably sealed accommodation space. The above main body 2 of the mobile power supply may be further mounted with a circuit board and a battery therein, the circuit board is connected to the battery, the above Bluetooth headset holder 21 may be provided with a charging port connected to the circuit board.

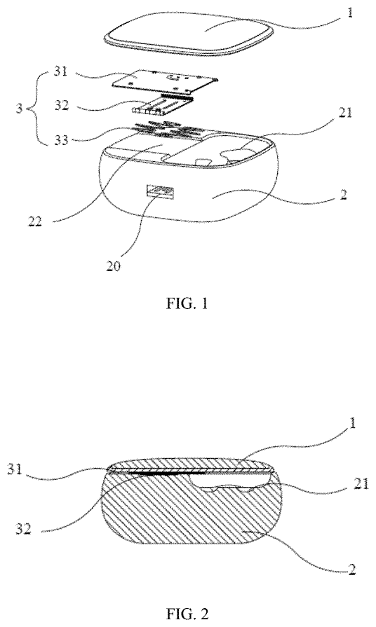

A first embodiment of the present invention is shown in FIGS. 1-4. The surface of the above main body 2 of the mobile power supply fitting with the cover body 1 may be formed with a mounting groove 22 for mounting the sliding connection assembly 3, which is located beside the Bluetooth headset holder 21, a height of the above mounting groove 22 is the same as a thickness of the sliding connection assembly 3, so that the cover body 1 can be attached to the surface of the main body 2 of the mobile power supply to keep the appearance neat. The above second connection member 32 is fixedly mounted in the mounting groove 22, two sides of the second connection member 32 that are parallel to an orientation of the mounting groove 22 protrude upward to be formed with side walls, opposing surfaces of two side walls may be formed with sliding grooves that are symmetrically disposed, an orientation of the sliding groove is consistent with that of the mounting groove 22, and two sides of the above first connection member are bent downward to be formed with sliding rails movably fitting with the above two sliding grooves, respectively.

At least one reset member 33 may be connected between the above first connection member 31 and second connection member 32, there are two reset members in this embodiment, the above reset member 33 may be a steel wire having at least one bend, and two ends of the steel wire are respectively connected to the first connection member 31 and the second connection member 32. When the cover body is in the sealed state, the steel wire is in the initial state, when the first connection member 31 is slid to make the cover body 1 be in an opened state, the bend is stretched and the steel wire generates tension to limit a moving range of the first connection member 31, which can prevent the first connection member 31 from being separated from the second connection member 32 due to excessive sliding, and can make the first connection member 31 be automatically reset.

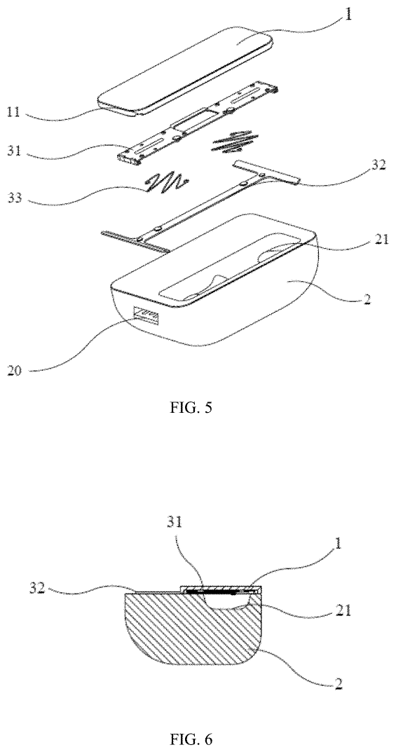

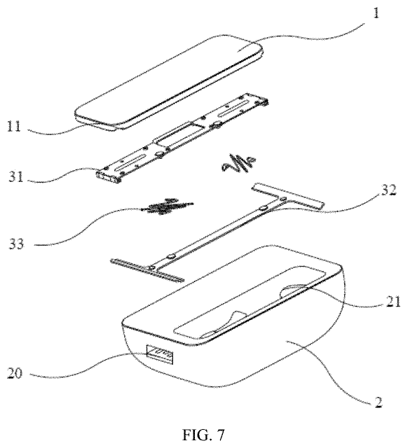

A second embodiment of the present invention is shown in FIGS. 5-8. A difference between the second embodiment and the first embodiment lies in the structure and mounting manner of the sliding connection assembly 3. The surface of the above cover body 1 fitting with the main body 2 of the mobile power supply may be formed with a mounting cavity for mounting the sliding connection assembly 3, the height of the above mounting cavity is the same as the thickness of the sliding connection assembly 3, so that the cover body 1 can be attached to the surface of the main body 2 of the mobile power supply to keep the appearance neat. The above first connection member 31 is fixedly mounted in the mounting cavity, the above side wall and sliding groove are formed on the first connection member 31, the second connection member 32 is bent upward to form a sliding rail, and the above mounting cavity may be formed with a notch 11 at a position corresponding to two ends of the sliding groove, so that the sliding rail of the second connection member 32 is able to be disposed to pass through the side wall and the sliding groove of the mounting cavity.

In the second embodiment, the second connection member 32 may be in a “ [symbol] ” shape, that is, a longitudinal bar is connected between two parallel lateral bars, the sliding rail thereof is disposed on the two lateral bars, and the above Bluetooth headset holder is located between the two lateral bars.

In the second embodiment, as same as the first embodiment, at least one reset member 33 may be connected between the first connection member 31 and the second connection member 32.

The above main body 2 of the mobile power supply may be further provided with the USB port 20 which is connected to the circuit board and can realize supplying power to other electronic apparatuses, thereby enriching the use of the present invention.

Through the above structure, the user only needs to operate the Bluetooth headset with single hand when picking and placing it, a palm grips the main body 2 of the mobile power supply, a thumb presses and moves the cover body 1 to a side of the main body 2 of the mobile power supply, at this time, the first connection member 31 is slidably connected to the second connection member 32, when the cover body 1 is opened to be in the state where it no longer blocks the Bluetooth headset holder 21, the Bluetooth headset can be placed in the Bluetooth headset holder 21 and charged, or the Bluetooth headset can be picked up, which is convenient and quick to operate and avoids waste of time, thereby improving the user experience.

In addition, when the operation of placing and picking the Bluetooth headset is completed, the above reset member 33 can make the first connection member 31 quickly reset to the initial state, that is, the cover body 1 is reset to be in the state of covering the Bluetooth headset holder 21, to prevent the user from forgetting to close the cover body 1 and causing the Bluetooth headset to be dropped and lost.

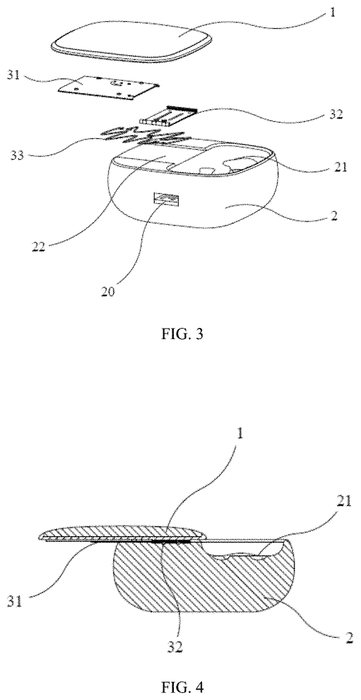

As shown in FIGS. 2, 4, 6 and 8 and in conjunction with structures of the first connection member and the second connection member of the sliding connection assembly, the cover body and the main body of the mobile power supply fit with each other surface-to-surface, thus, the relative moving manner between the cover body and the main body of the mobile power supply is that the cover body and the main body of the mobile power supply are slid face-to-face in parallel, so that the cover body is opened to no longer block the Bluetooth headset holder. The first connection member is in a plate shape, the second connection member is in a plate shape or a lath shape, the fit relationship between the two is that the first connection member and the second connection member fit with each other to form a guide sliding rail structure, and a sliding direction of the guide sliding rail structure is parallel to the surface of the cover body fitting with the main body of the mobile power supply.

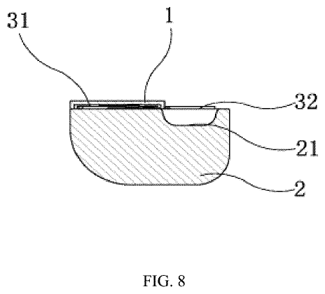

As shown in FIGS. 1, 3, 5 and 8, the main body of the mobile power supply may be provided with the USB port for supplying power to other electronic apparatuses, an extending direction of the USB port is in a vertical relationship with the sliding direction of the cover body relative to the main body of the mobile power supply, and the orientation of the USB port avoids generating interference when the cover body is slid. In the first embodiment, as shown in FIG. 2, in the initial state, the cover body is fully covered on the main body of the mobile power supply to form a full covering structure for the main body of the mobile power supply; and as shown in FIG. 4, when the cover body is opened, a portion of the cover body is slid to an outer side of the main body of the mobile power supply to no longer block the Bluetooth headset holder. In the second embodiment, as shown in FIG. 6, in the initial state, the cover body is covered on a recessed area of the main body of the mobile power supply to form a partial covering structure for the main body of the mobile power supply; as shown in FIG. 8, when the cover body is opened, the cover body is slid to a side of the recessed area to no longer block the Bluetooth headset holder and the cover body is not slid out to the outer side of the main body of the mobile power supply.

The above embodiments and drawings do not limit the product form and pattern of the present invention, and any proper changes or modifications made by those ordinary skilled in the art should be deemed as not departing from the patent scope of the present invention.

What is claimed is:

1. A sliding rail structure of a mobile power supply, comprising a cover body and a main body of the mobile power supply, a surface of the main body of the mobile power supply fitting with the cover body is recessed inwardly to form at least one Bluetooth headset holder for placing and charging the Bluetooth headset, wherein: a sliding connection assembly is connected between the cover body and the main body of the mobile power supply; the sliding connection assembly comprises a first connection member, a second connection member and a reset member, the first connection member is fixed on a surface of the cover body facing the main body of the mobile power supply, the second connection member is fixed on a surface of the main body of the mobile power supply facing the cover body, the first connection member is slidably connected to the second connection member, and the reset member is connected between the first connection member and the second connection member;
a user only needs to operate the Bluetooth headset with single hand when picking and placing it, a palm grips the main body of the mobile power supply, a thumb presses and moves the cover body to a side of the main body of the mobile power supply, and when the cover body is opened to be in a state where it no longer blocks the Bluetooth headset holder, the Bluetooth headset is able to be placed in the Bluetooth headset holder and charged, or the Bluetooth headset is able to be picked up; and
when an operation of picking and placing the Bluetooth headset is completed, the above reset member makes the first connection member quickly reset to an initial state.

2. The sliding rail structure of the mobile power supply according to claim 1, wherein: the cover body and the main body of the mobile power supply are slid face-to-face in parallel, so that the cover body is opened to no longer block the Bluetooth headset holder.

3. The sliding rail structure of the mobile power supply according to claim 2, wherein: the first connection member and the second connection member fit with each other to form a guide sliding rail structure, and a sliding direction of the guide sliding rail structure is parallel to a surface of the cover body fitting with the main body of the mobile power supply.

4. The sliding rail structure of the mobile power supply according to claim 1, wherein: a surface of the main body of the mobile power supply fitting with the cover body is formed with a mounting groove for mounting the sliding connection assembly, and the mounting groove is located beside the Bluetooth headset holder; and the second connection member is fixedly mounted in the mounting groove.

5. The sliding rail structure of the mobile power supply according to claim 4, wherein: the second connection member is formed with a sliding groove, an orientation of the sliding groove is consistent with that of the mounting groove, and the first connection member is formed with a sliding rail movably fitting with the sliding groove.

6. The sliding rail structure of the mobile power supply according to claim 1, wherein: a surface of the cover body fitting with the main body of the mobile power supply is formed with a mounting cavity for mounting the sliding connection assembly, and the first connection member is fixedly mounted in the mounting cavity.

7. The sliding rail structure of the mobile power supply according to claim 6, wherein: the first connection member is formed with a sliding groove, the second connection member is formed with the sliding rail movably fitting with the sliding groove, and the mounting cavity is formed with a notch through which the sliding rail is disposed to pass at a position corresponding to two ends of the sliding groove.

8. The sliding rail structure of the mobile power supply according to claim 1, wherein: the reset member is a steel wire having at least one bend, and two ends of the steel wire are respectively connected to the first connection member and the second connection member.

9. The sliding rail structure of the mobile power supply according to claim 3, wherein: the reset member is a steel wire having at least one bend, and two ends of the steel wire are respectively connected to the first connection member and the second connection member.

10. The sliding rail structure of the mobile power supply according to claim 1, wherein: the main body of the mobile power supply is provided with a USB port for supplying power to other electronic apparatuses, an extending direction of the USB port is in a vertical relationship with the sliding direction of the cover body relative to the main body of the mobile power supply.

11. The sliding rail structure of the mobile power supply according to claim 1, wherein: in the initial state, the cover body is fully covered on the main body of the mobile power supply to form a full covering structure for the main body of the mobile power supply; and when the cover body is opened, a portion of the cover body is slid to an outer side of the main body of the mobile power supply to no longer block the Bluetooth headset holder.

12. The sliding rail structure of the mobile power supply according to claim 1, wherein: in the initial state, the cover body is covered on a recessed area of the main body of the mobile power supply to form a partial covering structure for the main body of the mobile power supply; and when the cover body is opened, the cover body is slid to a side of the recessed area to no longer block the Bluetooth headset holder and the cover body is not slide out to the outer side of the main body of the mobile power supply.
